(19) United States
(12) Patent Application Publication
(10) Pub. No.: US 2015/0364253 A1
(43) Pub. Date: Dec. 17, 2015

(54) HEEL FILLET CAPACITOR WITH NOISE REDUCTION

(71) Applicant: Apple Inc., Cupertino, CA (US)

(72) Inventors: Shawn X. Arnold, Santa Cruz, CA (US); Dennis R. Pyper, San Jose, CA (US); Gang Ning, Santa Clara, CA (US); Meng Chi Lee, Los Altos, CA (US); Sascha Tietz, Sunnyvale, CA (US); Sury N. Darbha, San Jose, CA (US); Zhong-Qing Gong, Fremont, CA (US)

(21) Appl. No.: 14/500,794

(22) Filed: Sep. 29, 2014

Related U.S. Application Data
(60) Provisional application No. 62/011,514, filed on Jun. 12, 2014.

(51) Int. Cl. H01G 2/06; G10K 11/16; H01G 4/12; H05K 3/34; H05K 1/18

(52) U.S. Cl. CPC H01G 2/065; H05K 3/3431; H05K 1/181; H01G 4/12; G10K 11/16; H05K 2203/04

(57) ABSTRACT

Apparatus and methods are described for coupling a circuit component having piezoelectric properties, such as a ceramic capacitor, to a printed circuit board (PCB) by forming a first solder heel fillet and a second solder heel fillet that fixedly couple the circuit component to the PCB, where the first and second solder heel fillets have a height z that is less than a height h of the circuit component to reduce acoustic noise at the PCB caused by coupling the circuit component to the PCB. In various configurations, the first solder heel fillet and the second solder heel fillet can each fixedly coupled to: a bottom surface of the circuit component, a top surface of the PCB at a first solder pad and a second solder pad thereof, and a lower portion of each of a multiple side surfaces of the circuit component.

### CROSS REFERENCE TO RELATED APPLICATION(S)

This application claims the priority filing benefit of U.S. Provisional Application No. 62/011,514, filed on Jun. 12, 2014, and entitled “HEEL FILLET CAPACITOR,” which is incorporated by reference herein in its entirety for all purposes.

### FIELD

The described subject matter generally relates to manufacturing procedures and devices that can reduce unwanted acoustic noise at a printed circuit board (PCB), caused by various circuit-level components containing piezoelectric material.

### BACKGROUND

Many modern electronic devices use small form factor ceramic capacitors, such as multi-layer ceramic capacitors (MLCC), for such tasks as temporarily storing small amounts of power, decoupling power supplies, filtering electric signals, etc. However, the ceramic material of a ceramic capacitor can have a piezoelectric property causing the capacitor to expand and contract in response to applied electric fields emanating from a printed circuit board (PCB) to which the ceramic capacitor is attached. This expansion and contraction can cause portions of the ceramic capacitor to vibrate and thereby generate an audible noise within an electronic device, in proportion to an applied electric field intensity that operates at a frequency, or within a frequency range, that is audible to the human ear (e.g., between 20 Hz to 20 KHz).

In many hardware implementations, capacitor components can be very small, and as such, the vibration of individual capacitor components may be relatively insignificant in terms of the capacitor generating an audible noise in isolation. However, when there is an array of these circuit components vibrating at the same time, the cumulative audible effect may be increased. Further, when one or more ceramic capacitors are coupled (e.g., soldered) to a flexible substrate, such as a PCB, resulting vibrations can be further amplified. In this arrangement, a relatively benign problem can become a serious problem, particularly when a driving voltage varies within the audible frequency range. This problem may be manifested as a high-pitched noise emanating from an electronic device.

In an effort to address this problem, some systems and hardware engineers have focused on making various capacitor package modifications that minimize the physical coupling of a ceramic capacitor to a PCB, or alternatively, on placement of ceramic capacitors in tandem at a PCB to partially cancel each other out or otherwise reduce the amplification of a single vibrating capacitor. Unfortunately, these modifications often result in degraded performance of the capacitor component(s) when the physical changes to the capacitor coupling increases its impedance. Further, creative circuit layout solutions are generally limited in their ability to reduce or eliminate acoustic noise. In fact, in many scenarios, these solutions require undesirable compromises in device performance or space allocation at a PCB to implement.

Therefore, what is needed is a solution that effectively reduces acoustic noise caused by one or more ceramic capacitors, or other circuit components composed of piezoelectric material, vibrating within the housing of an electronic device without degrading device performance or detrimentally affecting various circuit design considerations.

### SUMMARY

This summary is provided to introduce (in a simplified form) a selection of concepts that are further described below in the Detailed Description. This summary is not intended to identify key features of the claimed subject matter, nor is it intended to be used as an aid in determining the scope of the claimed subject matter.

In accordance with some embodiments, an apparatus for reducing acoustic noise while maintaining component coupling reliability is discussed. The apparatus can include at least a substrate board and a circuit component having piezoelectric properties that is fixed to the substrate board via at least one coupling fillet, where the at least one coupling fillet is formed between a bottom surface of the circuit component and a top surface of the substrate board. Further, the at least one coupling fillet may be fixedly coupled to each of: the bottom surface of the circuit component, the top surface of the substrate board, and a lower portion of each of a plurality of side surfaces of the circuit component.

In accordance with some aspects, the circuit component can be a ceramic capacitor having piezoelectric properties that cause the ceramic capacitor to vibrate in response to applied electric fields, and the substrate board may be a printed circuit board (PCB) to which the ceramic capacitor is attached via the at least one coupling fillet. Additionally, the at least one coupling fillet can be a solder heel fillet that couples the ceramic capacitor to the PCB at opposing ends of the ceramic capacitor.

In other aspects of the disclosure, the at least one coupling fillet can be configured to have a height z that is less than a height h of the circuit component to reduce acoustic noise at the substrate board caused by the circuit component being fixed to the substrate board. In this regard, the height z of the at least one coupling fillet can be greater than 0% of the height h of the circuit component, but less than 20% of the height h of the circuit component. Alternatively, the height z of the at least one coupling fillet may be equal to 20% of the height h of the circuit component.

In various implementations, the substrate board can be a printed circuit board (PCB) having a plurality of solder pads printed thereon, and the circuit component may be fixed to the PCB at one or more solder pads of the plurality of solder pads with solder to form the at least one coupling fillet. Further, the dimensions of the one or more solder pads can be selected to cause the at least one coupling fillet to securely couple the circuit component to the PCB when a height z of the at least one coupling fillet is greater than 0% of a height h of the circuit component, but less than 20% of the height h of the circuit component. Alternatively, the dimensions of the one or more solder pads can be selected to cause the at least one coupling fillet to securely couple the circuit component to the PCB when a height z of the at least one coupling fillet is equal to 20% of a height h of the circuit component.

In one embodiment, the circuit component can be a multi-layer ceramic capacitor (MLCC) that is fixed to the substrate board via a solder heel fillet, such that the solder of solder heel fillet covers only a lower portion of each of the plurality of side surfaces of the MLCC. In this regard, the lower portion of each of the plurality of side surfaces of the MLCC may have a height z that is greater than 0% of the height h of the MLCC, but less than or equal to 20% of the height h of the MLCC.

In some configurations, an electronic device can include a printed circuit board (PCB), a circuit component having piezoelectric properties, and a first solder heel fillet and a second solder heel fillet that fixedly couple the circuit component to the PCB, where at least one of the first solder heel fillet and the second solder heel fillet can be configured to have a height z that is less than a height h of the circuit component to reduce acoustic noise at the PCB caused by coupling the circuit component to the PCB. In this embodiment, the first solder heel fillet and the second solder heel fillet can each be fixedly coupled to: a bottom surface of the circuit component, a top surface of the PCB at a first solder pad and a second solder pad thereof, and a lower portion of each of a plurality of side surfaces of the circuit component.

In one aspect, the circuit component can be a ceramic capacitor, and the first solder heel fillet and the second solder heel fillet can fixedly couple the ceramic capacitor to the PCB at opposing ends of the ceramic capacitor. Further, the first solder heel fillet can fixedly couple the ceramic capacitor to the PCB at a first solder pad of the PCB, and the second solder heel fillet can fixedly couple the ceramic capacitor to the PCB at a second solder pad of the PCB. In this regard, the first solder pad of the PCB may have a length dimension or a width dimension that is different than a corresponding length dimension or a corresponding width dimension of the second solder pad of the PCB.

In other aspects of the disclosure, the height z of the first solder heel fillet can be greater than 0% of the height h of the ceramic capacitor, but less than or equal to 20% of the height h of the ceramic capacitor.

In accordance with some implementations, a method for coupling a circuit component to a printed circuit board (PCB) to reduce acoustic noise resulting from the coupling can comprise means for disposing a first solder resist layer on a top surface of the circuit component, means for disposing a second solder resist layer on one or more side surfaces of the circuit component, such that a lower portion of each of the one or more side surfaces of the circuit component are not covered with the second solder resist layer, means for positioning the circuit component having the first solder resist layer and the second solder resist layer disposed thereon at the PCB, and means for coupling the circuit component to the PCB by forming at least one solder heel fillet at the lower portion of each of the one or more side surfaces of the circuit component, where the at least one solder heel fillet has a height z that less than the height h of the circuit component.

In some aspects, the method can also include means for coupling the circuit component to the PCB at one or more solder pads of the PCB by forming the at least one solder heel fillet on top of the one or more solder pads of the PCB.

### BRIEF DESCRIPTION OF THE DRAWINGS

The described embodiments and the advantages thereof may best be understood with reference to the following description taken in conjunction with the accompanying drawings. These drawings are not necessarily drawn to scale, and they are in no way intended to limit or exclude foreseeable modifications thereto in form and detail that may be made by one having ordinary skill in the art at the time of this disclosure.

FIG. 1A shows a top side view and a front side view of a ceramic capacitor, in accordance with some embodiments of the disclosure;

FIG. 1B shows a top side view and a front side view of the ceramic capacitor depicted in FIG. 1A after the ceramic capacitor has been at least partially covered with a solder resist layer, in accordance with some implementations of the disclosure;

FIG. 1C shows a top side view and a front side view of the ceramic capacitor depicted in FIG. 1B after the ceramic capacitor has been soldered onto a solder pad of printed circuit board (PCB), in accordance with various embodiments of the disclosure;

FIG. 1D shows a top side view and a front side view of the ceramic capacitor depicted in FIG. 1C identifying the heights of the ceramic capacitor and a solder heel fillet attaching the ceramic capacitor to the PCB, in accordance with various implementations of the disclosure;

FIG. 2 shows a top side view and a front side view of a ceramic capacitor having a tall solder heel fillet attaching the ceramic capacitor to the PCB, in accordance with some embodiments of the disclosure; and

FIG. 3 shows a top side view and a front side view of a ceramic capacitor without a solder heel fillet that is attached to the PCB only at bottom surfaces of the capacitor, in accordance with various implementations of the disclosure.

### DETAILED DESCRIPTION

Representative examples and implementations for a heel fillet capacitor with noise reduction are described within this section. These examples are provided to add context to, and to aid in the understanding of, the subject matter of this disclosure. It should be apparent to one having ordinary skill in the art that the present disclosure may be practiced with or without some of the specific details described herein. Further, various modifications and/or alterations can be made to the subject matter described herein, and illustrated in the corresponding figures, to achieve similar advantages and results, without departing from the spirit and scope of the disclosure.

References are made in this section to the accompanying figures, which form a part of the disclosure and in which are shown, by way of illustration, various implementations corresponding to the described embodiments herein. Although the embodiments of this disclosure are described in sufficient detail to enable one having ordinary skill in the art to practice the described implementations, it should be understood that these examples are not to be construed as being overly-limiting or all-inclusive.

In accordance with various implementations, the solder coupling a ceramic capacitor to a printed circuit board (PCB) can be a physical/mechanical interface that transfers piezoelectric and/or electro-strictive forces to the PCB resulting in unwanted human-audible noise. Limiting the usage of solder to an absolute minimum by overly applying solder resist coatings to various surfaces of ceramic capacitors can cause these capacitors to fail reliability testing, because these poorly attached capacitors can tear or shear off their respective terminals at the solder/PCB interface after a number of temperature/humidity cycles.

As such, one solution can be to increase the solder attachment of a ceramic capacitor to the PCB by removing a portion of the solder resist coating on the ceramic capacitor so that a solder heel fillet can be formed on the bottom and sides of the ceramic capacitor during manufacturing. In accordance with some embodiments of the disclosure, described further herein, a solder heel fillet that is greater than 0% and up to 20% of ceramic capacitor height may be adequate for improving the reliability of the ceramic capacitor's coupling to the PCB under extended temperature/humidity cycling due to the increased solder attachment of the ceramic capacitor to the PCB. This solder height can also minimize any resulting audible noise to occur within an acceptable range, from the perspective of system or circuit design engineers.

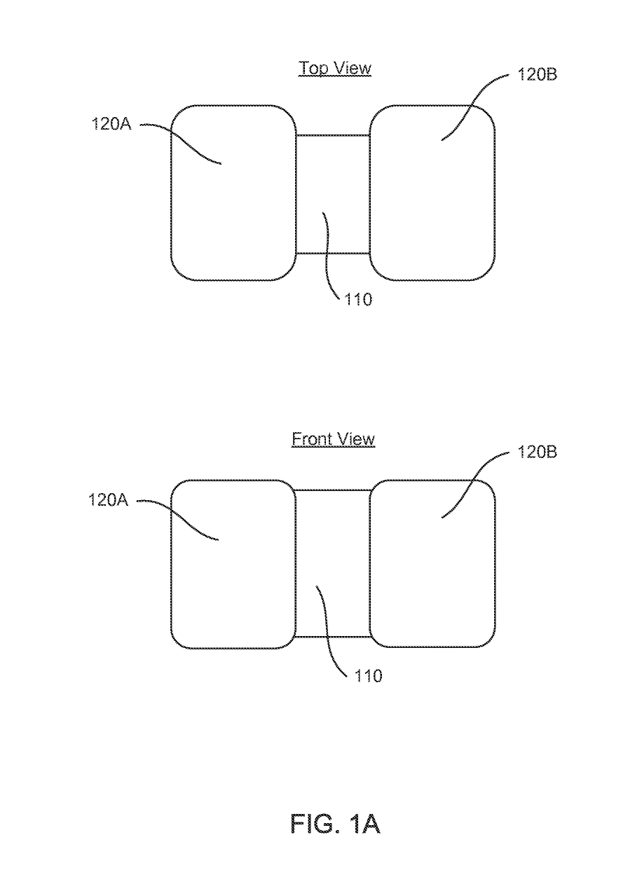

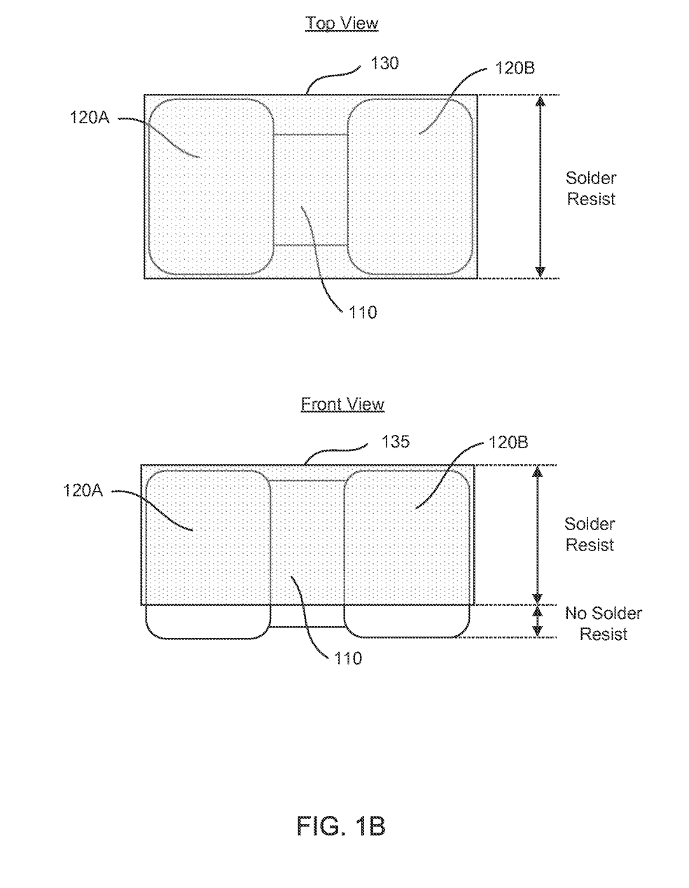

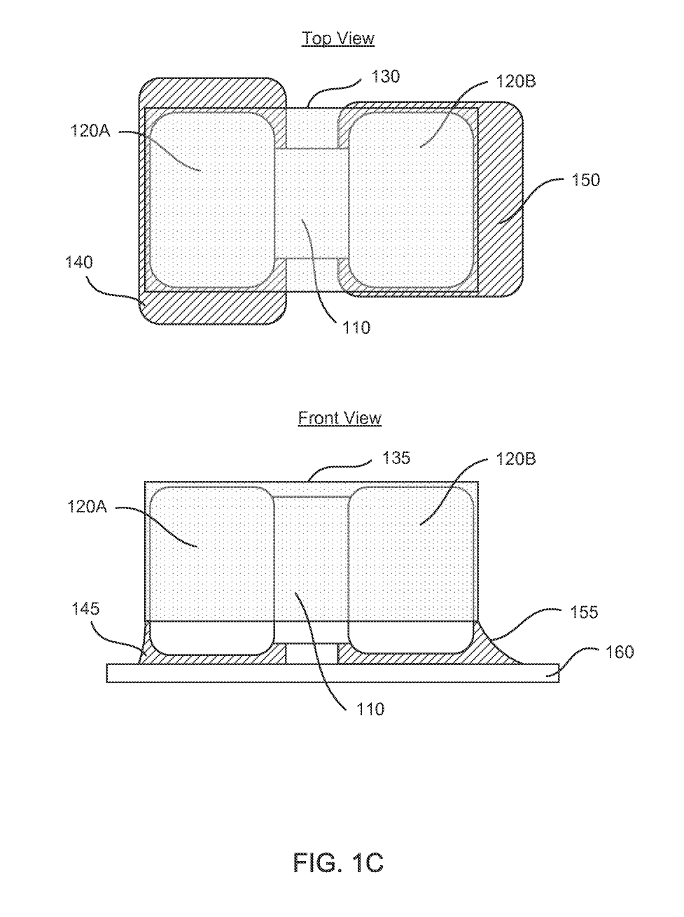

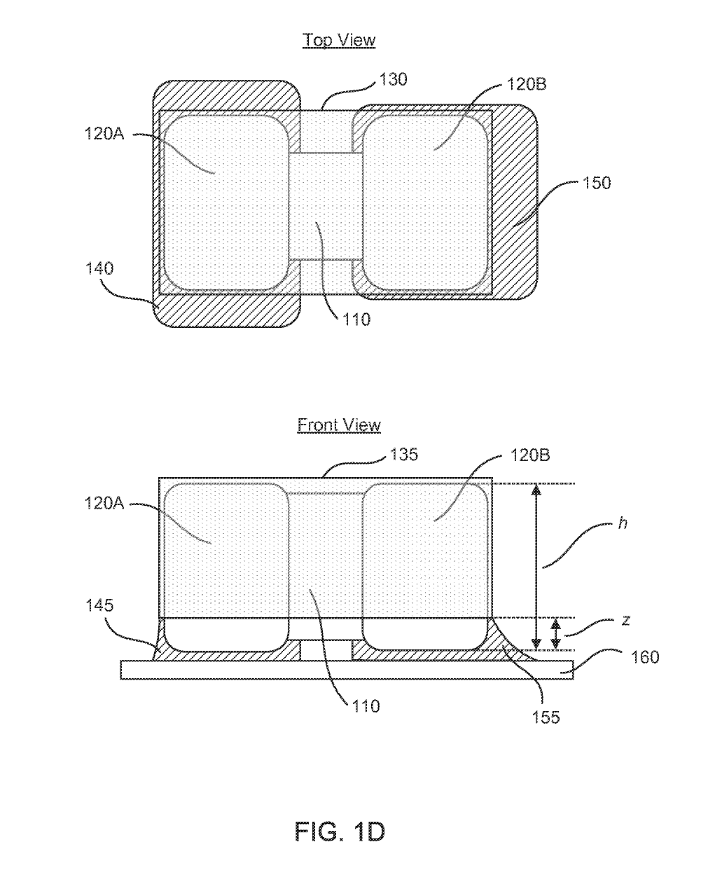

FIG. 1A shows a top side view and a front side view of a ceramic capacitor 100, in accordance with some exemplary embodiments of the disclosure. In one configuration, the ceramic capacitor 100 can have an insulated region 110, a first conductive terminal 120A, and a second conductive terminal 120B. The insulated region 110 of the ceramic capacitor is depicted as having a rectangular shape and the first and second conductive terminals, 120A and 120B, are depicted as having a rounded rectangular shape in an effort to simplify explanations and description within the cumulative disclosure. In this regard, it should be understood that the shape and build of the ceramic capacitor 100 can vary without departing from the spirit and scope of the disclosure.

In various arrangements, the first and second conductive terminals, 120A and 120B, may be electrically coupled, and mechanically attached, to a PCB using solder as a conductive coupling material. Further, the ceramic capacitor 100 can also be configured as a multi-layer ceramic capacitor (MLCC) having any conceivable number of sandwiched capacitive layers therein, without departing from the spirit and scope of the disclosure. Additionally, in some configurations, the ceramic capacitor 100 may be composed of any number of common types of material components, including piezoelectric material.

FIG. 1B shows a top side view and a front side view of the ceramic capacitor 100 depicted in FIG. 1A after the ceramic capacitor 100 has been at least partially covered with a solder resist layer, 130 and 135, in accordance with some implementations of the disclosure. As would be understood by those having ordinary skill in the art, solder resist is a coating that can be applied to one or more surfaces of a device component, such as the surface of a PCB or portions of a circuit-level component, to prevent solder from adhering to the surface(s) as well as to prevent oxidation. By way of example, solder resist may be applied during a fabrication process to a device or a device component as a thin lacquer-like layer of polymer.

Solder resist can also be referred to as a solder mask or a solder stop side mask. In various configurations, the ceramic capacitor 100 can be covered with any number of different types of a “non-solder attach” coating(s), without departing from the spirit and scope of the disclosure. By way of example, in FIG. 1B a solder resist layer 130 is applied over an upper surface of the ceramic capacitor 100, covering the first conductive terminal 120A, the insulated region 110, and the second conductive terminal 120B from the top. Further, a solder resist layer 135 is applied over the side surfaces of the ceramic capacitor 100, covering portions of the first conductive terminal 120A, the insulated region 110, and the second conductive terminal 120B (also shown in FIG. 1B).

In this regard, the solder resist layer 130 encloses the entire top side of ceramic capacitor 100, such that the entire top side surface of ceramic capacitor 100 is covered with solder resist 130. Further, the solder resist layer 135 encloses most of the front side surface of the ceramic capacitor 100, such that most of the front side surfaces of the ceramic capacitor 100 are covered with solder resist.

FIG. 1B further depicts a strip at the front side surface of ceramic capacitor 100 (adjacent to the bottom side of ceramic capacitor 100) that is not covered with a solder resist layer. Although not shown, it should be understood that the bottom surfaces of the ceramic capacitor 100 (arranged to face a PCB) are not covered with a solder resist layer. It should also be understood that the other three sides (e.g., the right side, the left side, and the back side), are configured in a manner similar as the front side of the ceramic capacitor 100, such that a strip of the surface that is adjacent to the bottom side is not covered with a solder resist layer. This configuration allows solder to adhere to the bottom side of ceramic capacitor 100 and to the strips of uncovered surface on the four sides (e.g., the front side, the right side, the left side, and the back side) of the ceramic capacitor 100, when applied during fabrication.

Specifically, solder can adhere these surfaces to the PCB at the first and second conductive terminals, 120A and 120B, of the ceramic capacitor 100 because these areas are exposed (e.g., by not having a solder resist layer covering). Further, the uncovered strips allow for the formation of a solder heel fillet, shown in FIG. 1C. In the above embodiment, there are no sides (other than the top side) of the ceramic capacitor 100 that have a solder resist layer that covers the entire corresponding side thereof. However, in other embodiments that are discussed further herein, a solder resist layer can be applied to cover the entire surface of one or more sides of the ceramic capacitor 100, without departing from the spirit and scope of the disclosure.

FIG. 1C shows a top side view and a front side view of the ceramic capacitor 100 depicted in FIG. 1B after the ceramic capacitor 100 has been soldered onto a corresponding solder pad, 140 and 150, of a PCB 160, in accordance with various embodiments of the disclosure. As described previously, the bottom side of ceramic capacitor 100 that faces the PCB 160 can be adhered thereto with solder during a manufacturing/fabrication process. In this regard, solder can be used to electrically couple, and mechanically attach, the first and second conductive terminals, 120A and 120B, of the ceramic capacitor 100 to the PCB 160 with the formation one or more low-profile couplings thereon.

Because there are uncovered surface strips on each of the four sides (e.g., the front side, the right side, the left side, and the back side) of the ceramic capacitor 100, one or more solder heel fillets, 145 and 155, can be formed to couple the ceramic capacitor 100 to the PCB 160 (e.g., in the manner shown in FIG. 1C). In various configurations, solder heel fillet 155 can be a first solder heel fillet that attaches the ceramic capacitor 100 to a solder pad area 150 of the PCB 160 when solder is applied during fabrication. FIG. 1C also depicts a second solder heel fillet 145 that attaches the ceramic capacitor 100 to another solder pad area 140 of the PCB 160, when soldered thereto. The second solder heel fillet 145 may have a smaller profile than the first solder heel fillet 155, because solder pad area 140 (associated with solder heel fillet 145) is smaller than solder pad area 150 (associated with solder heel fillet 155) along the axis shown in the front side view of FIG. 1C, as understood by those having ordinary skill in the art.

FIG. 1D shows a top side view and a front side view of the ceramic capacitor 100 depicted in FIG. 1C identifying the heights, h and z, of the ceramic capacitor 100 and a solder heel fillet, 145 and 155, attaching the ceramic capacitor 100 to the PCB 160, in accordance with various implementations of the disclosure. In this regard, height h of the ceramic capacitor 100 (having masked and unmasked portions) can be determined by the physical dimensions of the particular ceramic capacitor used, but height z of the solder heel fillets, 145 and 155, can be selected or assigned during manufacturing based on an amount of solder resist coverage applied on the corresponding sides (e.g., the front side, the right side, the left side, and the back side) of the ceramic capacitor 100. In various configurations, the height z can be selected to have a height that is greater than 0%, and less than or equal to 20%, of the height h of the ceramic capacitor 100 to reduce acoustic noise problems while still guaranteeing adequate solder coupling of the ceramic capacitor 100 to the PCB 160 to prevent tear offs or shear offs in response to extended use (e.g., after a number of temperature/humidity cycles).

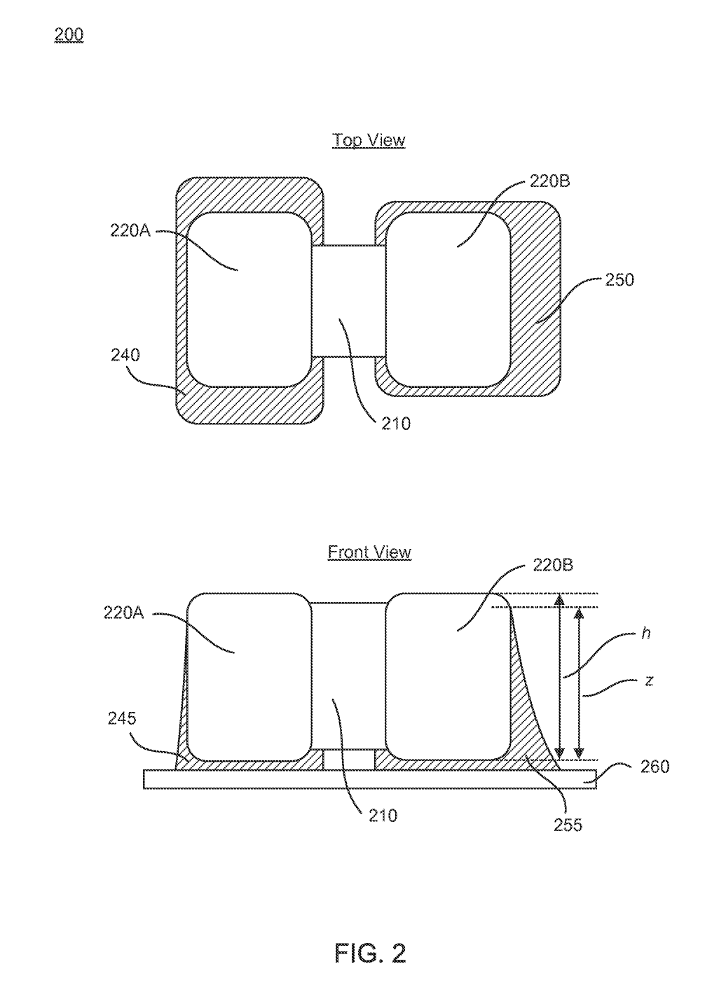

FIG. 2 shows a top side view and a front side view of a ceramic capacitor 200 having two tall solder heel fillets, 245 and 255, attaching the ceramic capacitor 200 to a PCB 260, in accordance with some embodiments of the disclosure. In FIG. 2, the ceramic capacitor 200 can have a first conductive terminal 220A, an insulated region 210, and a second conductive terminal 220B. In accordance with various embodiments, the first and the second conductive terminals, 220A and 220B, can be electrically coupled, and mechanically attached, to the PCB 260 using solder as a coupling implement. As understood by those having ordinary skill in the art, this coupling may occur during a manufacturing process that attaches the ceramic capacitor 200 to the PCB 260.

In this regard, during fabrication, solder can be applied at a first solder pad area 250 to form a first tall solder heel fillet 255, and solder can also be applied at a second solder pad area 240 to form a second tall solder heel fillet 245. For the first and second tall solder heel fillets, 245 and 255, the height z may be large enough to cover a majority of the sides (e.g., the front side, the right side, the left side, and the back side) of the ceramic capacitor 200, as depicted in FIG. 2. During a corresponding manufacturing process, no solder resist layer(s) may be applied at the ceramic capacitor 100, so height z of the tall solder heel fillets, 245 and 255, can be configured to be near or equal to height h of the ceramic capacitor 200.

However, in this arrangement, the tall solder heel fillets, 245 and 255, of the ceramic capacitor 200 can be attached to the PCB 260 in a manner that detrimentally produces human-audible noise. Specifically, the tall solder heel fillets, 245 and 255, of FIG. 2 may transfer large vibrational forces to the PCB 260 due in part to the piezoelectric properties of the ceramic capacitor 200, thereby causing the capacitor 200 to generate an audible noise within an electronic device (not shown), in proportion to an applied electric field intensity that operates at a frequency, or within a frequency range, that is audible to the human ear (e.g., between 20 Hz to 20 KHz).

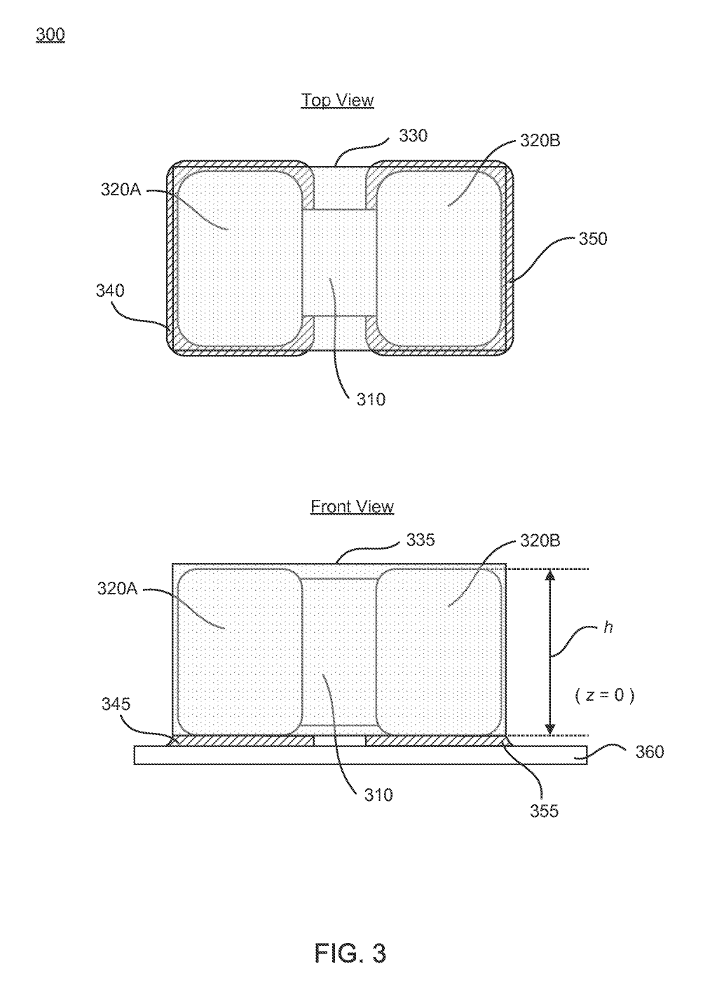

FIG. 3 shows a top side view and a front side view of a ceramic capacitor 300 without a solder heel fillet (e.g., “zero” solder heel fillet, where z=0) that is attached to the PCB 360 only at bottom surfaces of the capacitor 300, in accordance with various implementations of the disclosure. In some embodiments, the ceramic capacitor 300 can have a first conductive terminal 320A, an insulated region 310, and a second conductive terminal 320B. In various configurations, the first and the second conductive terminals, 320A and 320B, can be electrically coupled, and mechanically attached, to a PCB 360 using solder as a coupling implement. In this arrangement, solder can be applied to a first solder pad area 350 of the PCB 360 to form a first solder structure 355, and solder can also be applied to a second solder pad area 340 of the PCB 360 to form a second solder structure 345.

In this scenario, neither the first solder structure 355 nor the second solder structure 345 is configured with a solder heel fillet. To fabricate the first solder structure 355 and the second solder structure 345 one or more solder resist layer(s), 330 and 335, can be applied to the ceramic capacitor 300 to cover all sides (e.g., the top side, the front side, the right side, the left side, and the back side) thereof, except for the bottom side. Specifically, in an embodiment, a first solder resist layer 330 can be is applied over all top side surfaces of the ceramic capacitor 300. Further, a second solder resist layer 335 can be applied to all sides (e.g., the front side, the right side, the left side, and the back side) of the ceramic capacitor 300. Therefore, only the bottom side (the side facing the PCB 360) of the ceramic capacitor 300 is not covered with a solder resist layer. Accordingly, no solder heel fillet is formed at the ceramic capacitor 300 (e.g., where z=0).

Unlike the ceramic capacitor 200 FIG. 2 (having high solder heel fillets), the ceramic capacitor 300 of FIG. 3 will transfer minimal piezoelectric and electro-strictive forces to the PCB 360, resulting in almost no human audible noise, which is desirable. However, the ceramic capacitor 300 with no solder heel fillet can fail reliability testing, which undesirable. In particular, the ceramic capacitor 300 can tear or shear off terminals at the solder/PCB interface after a number of temperature/humidity cycles. Further, a coefficient of thermal expansion (CTE) mismatch at the ceramic capacitor 300 can create additional mechanical stresses during temperature/humidity cycling that may also cause the ceramic capacitor 300 to tear or shear off the PCB 360 with extended use.

Therefore, a tall solder heel fillet (e.g., with z almost equal to h) may cause maximum acoustic noise, whereas, no solder heel fillet (e.g., a zero height, with z=0) can cause minimum acoustic noise, but this configuration may fail reliability testing for the reasons described above. Accordingly, selecting an appropriate value of z as a solder heel fillet height (e.g., between 0% and 20% of h) can minimize acoustic noise to an acceptable level, while preventing sheer off or tear off of a corresponding ceramic capacitor. In some configurations, a solder heel fillet having a height z that is close to 20% of ceramic capacitor height h can be ideal for various circuit design considerations.

As such, in one embodiment for reduced acoustic noise with adequate reliability, z can be equal to or 20% of h. In a another embodiment, for reduced acoustic noise with adequate reliability, z can equal any value that is greater than 0% of h, but less than or equal to 20% of h. In other embodiments, for reduced acoustic noise with adequate reliability, z can be any value that is higher than 20% of h, but less than 40% of h, such as when reliability is deemed to more desirable than noise reduction. Further, in some fabrication implementations, z can be modified by varying the solder pad dimensions at the PCB, as discussed above with respect to FIGS. 1C and 1D, above. Accordingly, in some embodiments, acoustic noise reduction can be achieved by decreasing one or more solder pad dimensions/areas at the PCD, to minimize, but not eliminate, the creation of a corresponding solder heel fillet, as would be understood by those having ordinary skill in the art.

The foregoing description, for purposes of explanation, used specific nomenclature to provide a thorough understanding of the described embodiments. However, it will be apparent to one skilled in the art that some of the specific details are not required in order to practice the described embodiments. Thus, the foregoing descriptions of specific embodiments are presented herein for purposes of illustration and description. These descriptions are not intended to be exhaustive, all-inclusive, or to limit the described embodiments to the precise forms or details disclosed. It will be apparent to one of ordinary skill in the art that many modifications and variations are possible in view of the above teachings, without departing from the spirit and the scope of the disclosure.

What is claimed is:

1. An apparatus for reducing acoustic noise while maintaining component coupling reliability, the apparatus comprising:
a substrate board; and
a circuit component having piezoelectric properties that is fixed to the substrate board via at least one coupling fillet,
wherein the at least one coupling fillet is formed between a bottom surface of the circuit component and a top surface of the substrate board, such that the at least one coupling fillet is fixedly coupled to each of:
i. the bottom surface of the circuit component;
ii. the top surface of the substrate board; and
iii. a lower portion of each of a plurality of side surfaces of the circuit component.

2. The apparatus of claim 1, wherein the circuit component is a ceramic capacitor having piezoelectric properties that cause the ceramic capacitor to vibrate in response to applied electric fields, and the substrate board is a printed circuit board (PCB) to which the ceramic capacitor is attached via the at least one coupling fillet.

3. The apparatus of claim 2, wherein the at least one coupling fillet is a solder heel fillet that couples the ceramic capacitor to the PCB at opposing ends of the ceramic capacitor.

4. The apparatus of claim 1, wherein the at least one coupling fillet is configured to have a height z that is less than a height h of the circuit component to reduce acoustic noise at the substrate board caused by the circuit component being fixed to the substrate board.

5. The apparatus of claim 4, wherein the height z of the at least one coupling fillet is greater than 0% of the height h of the circuit component, but less than 20% of the height h of the circuit component.

6. The apparatus of claim 4, wherein the height z of the at least one coupling fillet is equal to 20% of the height h of the circuit component.

7. The apparatus of claim 1, wherein:
the substrate board is a printed circuit board (PCB) having a plurality of solder pads printed thereon; and
the circuit component is fixed to the PCB at one or more solder pads of the plurality of solder pads with solder to form the at least one coupling fillet.

8. The apparatus of claim 7, wherein dimensions of the one or more solder pads are selected to cause the at least one coupling fillet to securely couple the circuit component to the PCB when a height z of the at least one coupling fillet is greater than 0% of a height h of the circuit component, but less than 20% of the height h of the circuit component.

9. The apparatus of claim 7, wherein dimensions of the one or more solder pads are selected to cause the at least one coupling fillet to securely couple the circuit component to the PCB when a height z of the at least one coupling fillet is equal to 20% of a height h of the circuit component.

10. The apparatus of claim 1, wherein the circuit component is a multi-layer ceramic capacitor (MLCC) that is fixed to the substrate board via a solder heel fillet, such that solder of solder heel fillet covers only a lower portion of each of the plurality of side surfaces of the MLCC.

11. The apparatus of claim 10, wherein the lower portion of each of the plurality of side surfaces of the MLCC has a height z that is greater than 0% of a height h of the MLCC, but less than or equal to 20% of the height h of the MLCC.

12. An electronic device, comprising:
a printed circuit board (PCB);
a circuit component having piezoelectric properties; and
a first solder heel fillet and a second solder heel fillet that fixedly couple the circuit component to the PCB,
wherein at least one of the first solder heel fillet and the second solder heel fillet are configured to have a height z that is less than a height h of the circuit component to reduce acoustic noise at the PCB caused by coupling the circuit component to the PCB.

13. The electronic device of claim 12, wherein the first solder heel fillet and the second solder heel fillet are each fixedly coupled to: a bottom surface of the circuit component, a top surface of the PCB at a first solder pad and a second solder pad thereof, and a lower portion of each of a plurality of side surfaces of the circuit component.

14. The electronic device of claim 12, wherein:
the circuit component is a ceramic capacitor; and
the first solder heel fillet and the second solder heel fillet fixedly couple the ceramic capacitor to the PCB at opposing ends of the ceramic capacitor.

15. The electronic device of claim 14, wherein:
the first solder heel fillet fixedly couples the ceramic capacitor to the PCB at a first solder pad of the PCB, and the second solder heel fillet fixedly couples the ceramic capacitor to the PCB at a second solder pad of the PCB; and
the first solder pad of the PCB has a length dimension or a width dimension that is different than a corresponding length dimension or a corresponding width dimension of the second solder pad of the PCB.

16. The electronic device of claim 12, wherein the height z of the first solder heel fillet is greater than 0% of the height h of the circuit component, but less than or equal to 20% of the height h of the circuit component.

17. A method for coupling a circuit component to a printed circuit board (PCB) to reduce acoustic noise resulting from the coupling, the method comprising:
means for disposing a first solder resist layer on a top surface of the circuit component;
means for disposing a second solder resist layer on one or more side surfaces of the circuit component, such that a lower portion of each of the one or more side surfaces of the circuit component are not covered with the second solder resist layer;
means for positioning the circuit component having the first solder resist layer and the second solder resist layer disposed thereon at the PCB; and
means for coupling the circuit component to the PCB by forming at least one solder heel fillet at the lower portion of each of the one or more side surfaces of the circuit component,
wherein the at least one solder heel fillet has a height z that less than a height h of the circuit component.

18. The method of claim 17, wherein:
the circuit component is a ceramic capacitor; and
the height z of at least one solder heel fillet is greater than 0% of the height h of the ceramic capacitor, but less than 20% of the height h of the ceramic capacitor.

19. The method of claim 17, further comprising means for coupling the circuit component to the PCB at one or more solder pads of the PCB by forming the at least one solder heel fillet on top of the one or more solder pads of the PCB.

20. The method of claim 17, wherein:
the circuit component is a multi-layer ceramic capacitor (MLCC); and
the height z of at least one solder heel fillet is equal to 20% of the height h of the MLCC.
